(19) United States
(12) Patent Application Publication
(10) Pub. No.: US 2024/0218297 A1
(43) Pub. Date: Jul. 4, 2024

(54) SEMICONDUCTOR CLEANING COMPOSITION AND METHOD OF MANUFACTURING SEMICONDUCTOR USING THE SAME

(71) Applicant: SAMSUNG ELECTRONICS CO., LTD., Suwon-si (KR)

(72) Inventors: DAESUNG CHUNG, Pohang-si (KR); HAYOUNG JEON, Suwon-si (KR); JI HOON CHA, Suwon-si (KR); MINGYU JAE, Pohang-si (KR); KYUNGHYUN KIM, Suwon-si (KR); SUNGHOON YOO, Pohang-si (KR)

(73) Assignee: Postech Research and Business Development Foundation, Pohang-si (KR)

(21) Appl. No.: 18/244,336

(22) Filed: Sep. 11, 2023

(30) Foreign Application Priority Data
Jan. 2, 2023 (KR) 10-2023-0000339

(51) Int. Cl. C11D 3/37; C11D 3/20; C11D 3/43; C11D 11/00

(52) U.S. Cl. CPC C11D 3/3746; C11D 3/2082; C11D 3/43; C11D 11/0047

(57) ABSTRACT

A semiconductor cleaning composition includes: a hydrophobic polymer, an organic acid; and a solvent, wherein the hydrophobic polymer includes a first allotrope and a second allotrope, wherein the first allotrope is nonpolar, wherein the second allotrope is polar, and wherein the second allotrope is about 5% to about 20% of the hydrophobic polymer.

### CROSS-REFERENCE TO RELATED APPLICATION

This U.S. non-provisional patent application claims priority under 35 U.S.C. § 119 to Korean Patent Application No. 10-2023-0000339, filed on Jan. 2, 2023 in the Korean Intellectual Property Office, the disclosure of which is incorporated by reference herein in its entirety.

### TECHNICAL FIELD

The present inventive concept relates to a semiconductor cleaning composition and a method of manufacturing a semiconductor using the same, and more particularly, to a semiconductor cleaning composition including a hydrophobic polymer.

### DISCUSSION OF THE RELATED ART

A semiconductor device may be manufactured through various processes. For example, the semiconductor device may be manufactured through a photo process, an etching process, a deposition process, a cleaning process, and a polishing process for a wafer such as silicon. Among them, the cleaning process is typically a process performed between the processes, and is a process of removing contaminants that may be generated during a semiconductor manufacturing process from a wafer surface. As the semiconductor process manufactures semiconductors that are more miniaturized, higher in density, higher in integration, and higher in performance, the contaminants on the wafer surface may negatively affect the yield and quality reliability of semiconductor products. Therefore, an effective cleaning process for cleaning the wafer surface is desirable in the semiconductor process.

### SUMMARY

According to some embodiments of the present inventive concept, a semiconductor cleaning composition includes: a hydrophobic polymer; an organic acid; and a solvent, wherein the hydrophobic polymer includes a first allotrope and a second allotrope, wherein the first allotrope is nonpolar, wherein the second allotrope is polar, and wherein the second allotrope is about 5% to about 20% of the hydrophobic polymer.

According to some embodiments of the present inventive concept, a method of manufacturing a semiconductor includes: providing a cleaning solution; spraying the cleaning solution on a substrate; forming a thin film on the substrate by using the cleaning solution; and spraying distilled water on the thin film, wherein the cleaning solution includes a hydrophobic polymer and an organic acid, and wherein the thin film is separated from the substrate by the spraying of the distilled water.

According to some embodiments of the present inventive concept, a method of manufacturing a semiconductor includes: providing a cleaning solution including a semiconductor cleaning composition; spraying the cleaning solution on a substrate; forming a thin film on the substrate by using the cleaning solution; spraying distilled water on the thin film; and spraying acetone on the substrate, wherein the thin film is separated from the substrate by the spraying of the distilled water, wherein the semiconductor cleaning composition includes: a hydrophobic polymer; an organic acids; and a solvent, wherein the hydrophobic polymer includes a first allotrope and a second allotrope, wherein the first allotrope is nonpolar, wherein the second allotrope is polar, wherein the second allotrope is about 6% to about 10% of the hydrophobic polymer, wherein a concentration of the hydrophobic polymer is about 5 to about 7 wt %, and wherein a concentration of the organic acid is about 1 to about 1.5 wt %.

### BRIEF DESCRIPTION OF THE DRAWINGS

The above and other features of the present inventive concept will become more apparent by describing in detail exemplary embodiments thereof, with reference to the accompanying drawings, in which:

FIG. 1 is a flowchart illustrating a method of manufacturing a semiconductor according to some embodiments of the present inventive concept.

FIGS. 2, 3 and 4 are schematic diagrams for illustrating a method of manufacturing a semiconductor according to some embodiments of the present inventive concept.

FIG. 5A shows an AFM image and an SEM image of a bare-Si substrate.

FIG. 5B shows an AFM image and an SEM image of a bare-Si substrate after performing a cleaning process.

FIG. 6A is an image obtained by measuring a contact angle of DIW on a thin film.

FIG. 6B is an image obtained by measuring a contact angle of DIM on a thin film.

FIG. 7A is a graph illustrating cleaning efficiency of SiO₂ contaminant particles on a hydrophobic substrate.

FIG. 7B is a graph illustrating cleaning efficiency of SiN contaminant particles on a hydrophobic substrate.

FIG. 8A is a graph illustrating cleaning efficiency of SiO₂ contaminant particles on a hydrophilic substrate.

FIG. 8B is a graph illustrating cleaning efficiency of SiN contaminant particles on a hydrophilic substrate.

### DETAILED DESCRIPTION OF THE EMBODIMENTS

Hereinafter, a semiconductor cleaning composition according to embodiments of the present inventive concept and a method of manufacturing a semiconductor using the same will be described in detail with reference to the accompanying drawings.

It is to be understood that “about” or “approximately” as used herein is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” can mean within one or more standard deviations, or within ±30%, 20%, 10% or 5% of the stated value.

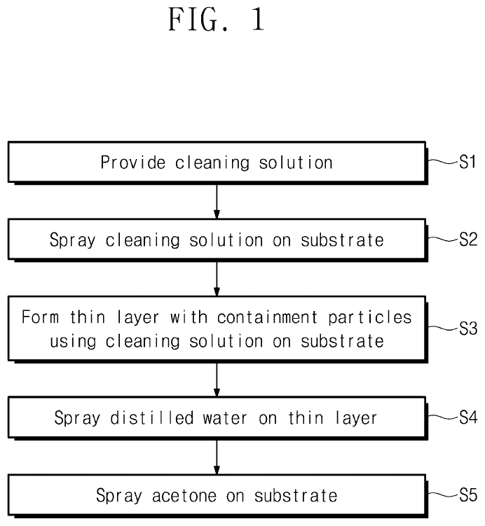

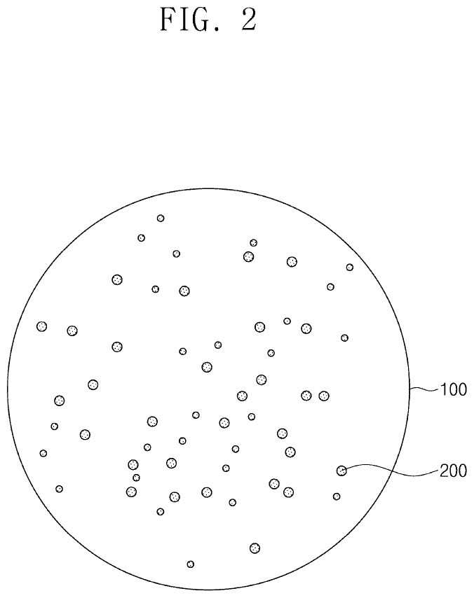

FIG. 1 is a flowchart illustrating a method of manufacturing a semiconductor according to some embodiments of the present inventive concept. FIGS. 2 to 4 are schematic diagrams for illustrating a method of manufacturing a semiconductor according to some embodiments of the present inventive concept.

Referring to FIG. 1, a method of manufacturing a semiconductor according to some embodiments of the present inventive concept may include a cleaning process. The cleaning process may include providing a cleaning solution S1, spraying the cleaning solution on a substrate S2, forming a thin film (or, e.g., a thin layer) with containment particles and the cleaning solution on the substrate S3, and spraying distilled water on the thin film S4, and spraying acetone on the substrate S5.

The cleaning solution may be provided in a first step S1. The cleaning solution may include a semiconductor cleaning composition. The semiconductor cleaning composition may include a hydrophobic polymer, an organic acid, and a solvent. For example, the semiconductor cleaning composition may be prepared by stirring the hydrophobic polymer, the organic acid, and the solvent.

The hydrophobic polymer may include a first allotrope and a second allotrope. The first allotrope may be nonpolar. The second allotrope may be polar. A ratio of the second allotrope may be about 5% to about 20% of the hydrophobic polymer. For example, the second allotrope may be about 5% to about 20% of the hydrophobic polymer. A ratio of the second allotrope may be, for example, about 6% to about 10% of the hydrophobic polymer. The hydrophobic polymer may have low surface energy. The hydrophobic polymer may include, for example, poly(vinylidene fluoride) (PVDF) or a PVDF copolymer.

According to an embodiment of the present inventive concept, the hydrophobic polymer may include a PVDF polymer. The PVDF polymer may be represented by Formula 1 below.

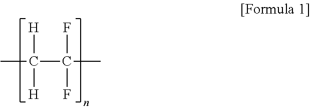

In Formula 1, ‘n’ may be an integer from 2,500 to 11,000. An average molecular weight (Mw) of the PVDF polymer may be about 180 to about 700 kg/mol.

The PVDF polymer may include a first PVDF allotrope and a second PVDF allotrope. The first PVDF allotrope may be nonpolar. The second PVDF allotrope may be polar. The first PVDF allotrope may be represented by Formula 2 below.

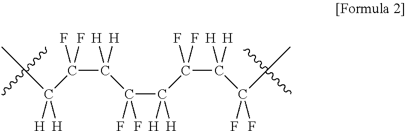

The second PVDF allotrope may be represented by Formula 3 below.

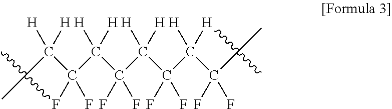 [SMILES: *CC(F)(F)CC(F)(F)CC(F)(F)CC(*)(F)F]

The first PVDF allotrope may be nonpolar such that fluorine (F) is located on both sides of carbon (C). The second PVDF allotrope may be polar such that fluorine (F) is located on one side of carbon (C). The second PVDF allotrope may be about 8% of the PVDF polymer.

For example, the hydrophobic polymer may be a poly(vinylidene fluoride-co-hexafluoropropylene) (PVDF-HFP) copolymer. The PVDF-HFP copolymer may be represented by Formula 4 below.

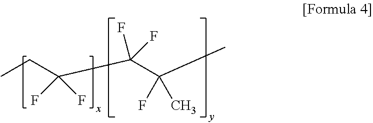

In Formula 4, y/(x+y) may be 0.05 to 0.2. An average molecular weight (Mw) of the PVDF-HFP copolymer may be about 400,000 g/mol. The PVDF-HFP copolymer may include HFP of about 5 to about 20 wt %.

Solubility parameters of the PVDF polymer and the PVDF-HFP copolymer may be shown in Table 1 below.

TABLE 1

| | δD, dispersion | δP, polar | δH, hydrogen | δ, solubility |
|---|---|---|---|---|
| Hydrophobic | force | force | bond force | parameter |
| polymer | (MPa^{1/2}) | (MPa^{1/2}) | (MPa^{1/2}) | (MPa^{1/2}) |
| PVDF | 17.1 | 12.6 | 10.6 | 23.2 |
| PVDF-HFP | 19.9 | 12.8 | 11.6 | 26.4 |

The organic acid may be hydrophilic. For example, the organic acid may be a low molecular weight organic acid. The organic acid may include at least one of, for example, oxalic acid, malic acid, and citric acid. The organic acid may be, for example, oxalic acid. The organic acid may be bound to the second allotrope of the hydrophobic polymer.

The solvent may be an amide-based solvent or a ketone-based solvent. The amide-based solvent may include at least one of, for example, dimethylformamide (DMF) and/or dimethylacetamide (DMA). The ketone-based solvent may include, for example, acetone. The solvent may include dimethyl sulfoxide (DMSO). The solvent may be, for example, dimethylformamide (DMF), dimethylacetamide (DMA), dimethyl sulfoxide (DMSO), or a combination thereof. The solvent may be, for example, a combination of DMF and DMA. The solvent may be, for example, a solvent in which DMF and DMA are combined in a volume fraction of about 24:76. The solvent may be, for example, a solvent in which DMF and acetone are combined in a volume fraction of about 80:20. A density of the solvent may be represented by Table 2 below.

TABLE 2

| | | | | DMA(88%)- | DMA(76%)- |
|---|---|---|---|---|---|
| Solvent | DMA | DMF | DMSO | DMSO(12%) | DMF(24%) |
| Density (g/cm³) | 0.940 | 0.944 | 1.1 | 0.959 | 0.941 |

The providing of the semiconductor cleaning composition may be performed by dissolving about 50 to about 70 g of the hydrophobic polymer and about 10 to about 15 g of the organic acid in 1 L of the solvent. A concentration of the hydrophobic polymer may be about 5 to about 7 wt %. A concentration of the organic acid may be about 1 to about 1.6 wt %. After mixing the hydrophobic polymer and the organic acid in the solvent, the cleaning solution may be formed by stirring. For example, the cleaning solution may be provided by stirring the semiconductor cleaning composition at about 70° C. for about 3 hours.

Referring to FIGS. 1 and 2, the cleaning solution may be sprayed onto the substrate 100 in a second step S2. The substrate 100 may be a hydrophilic substrate or a hydrophobic substrate. The hydrophilic substrate may be a substrate used in a front-end of line (FEOL) process during semiconductor manufacturing process. The hydrophilic substrate may include a semiconductor substrate (e.g., bare Si) or a first layer formed on the semiconductor substrate. The first layer may include at least one of, for example, SiN, poly-Si, and/or TIN. The hydrophobic substrate may be a substrate used in a back-end of line (BEOL) process during semiconductor manufacturing process. The hydrophobic substrate may include a second layer formed on the semiconductor substrate, and the second layer may include at least one of, for example, Cu, Co, and/or Low-k SiOCH.

Contaminant particles 200 may be provided on the substrate 100. For example, the contaminant particles 200 may be dispersed on an upper surface of the substrate 100. The contaminant particles 200 may be contaminants generated or introduced during the semiconductor manufacturing process. The contaminant particles 200 may include at least one of, for example, SiN and/or SiO₂.

For example, the cleaning solution may be sprayed on the substrate 100 by spin coating or spray coating. For example, the spin coating may be performed at about 500 rpm to about 2000 rpm for about 60 seconds.

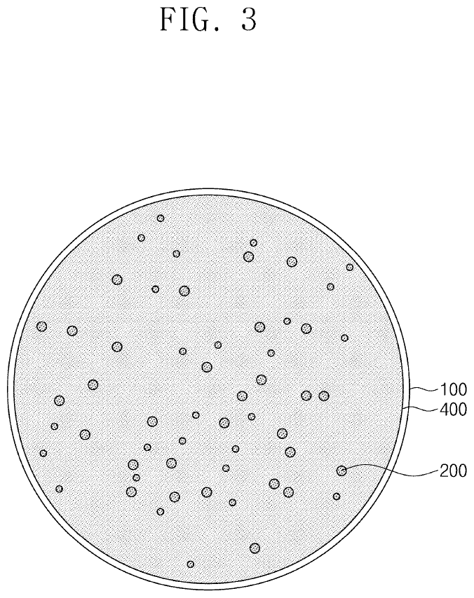

Referring to FIGS. 1 and 3, the cleaning solution and the contaminant particles 200 may form the thin film 400 on the substrate 100. The cleaning solution may adsorb or capture the contaminant particles 200 while being sprayed onto the substrate 100 to form the thin film 400 on the substrate 100. The thin film 400 may adsorb or capture the contaminant particles 200 without damaging a surface of the substrate 100. For example, the cleaning solution may form the thin film 400, and the thin film 400 may absorb or capture the contaminant particles 200. For example, the thin film 400 may be formed on the contaminant particles 200.

After the forming of the thin film 400, a heating process may be further included to evaporate the solvent in the cleaning solution. However, as the thin film 400 is not peeled off when an adhesive force between the thin film 400 and the substrate 100 is relatively strong, the heating process may be performed for about 60 seconds or less, for example.

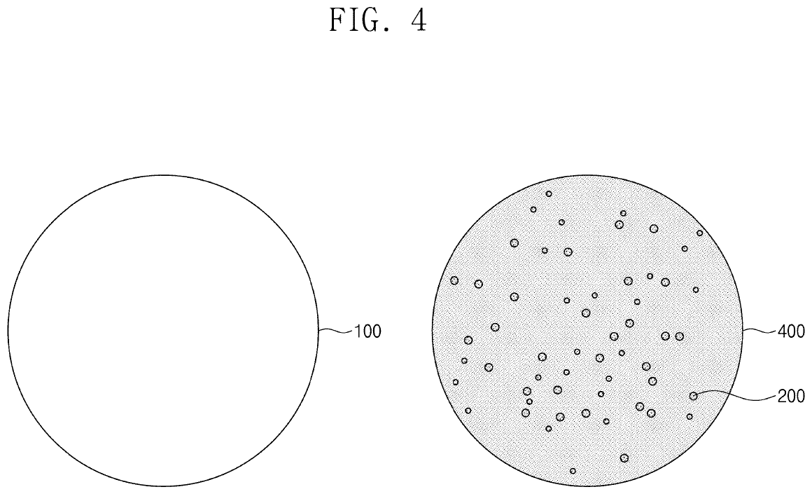

Referring to FIGS. 1 and 4, distilled water may be sprayed onto the thin film 400. The distilled water may be deionized water (DIW). By spraying distilled water on the thin film 400, the thin film 400 may be peeled from the substrate 100. Here, the thin film 400 may be peeled off together with the adsorbed or captured contaminant particles 200. The nonpolar first allotrope of the hydrophobic polymer may easily adsorb or capture the contaminant particles 200. The organic acid may be bonded to the polar second allotrope of the hydrophobic polymer, and thus, it may be easy to be peeled by using the distilled water. For example, the spraying of the distilled water may be performed for about 40 seconds at about 500 rpm to about 1000 rpm. Thus, the substrate 100 from which the contaminant particles 200 are removed may be provided.

The cleaning process may further include spraying acetone on the substrate 100 after the thin film 400 is peeled off. The spraying of the acetone may be performed for about 40 seconds at about 500 rpm to about 1000 rpm.

Hereinafter, a semiconductor cleaning composition and a cleaning process will be described with reference to experimental examples of the present inventive concept.

### Preparation Of Semiconductor Cleaning Composition (Cleaning Solution)

About 50 mg of PVDF polymer and about 10 mg of oxalic acid were added to about 1 mL of a solvent in which DMF and DMA were mixed at a volume fraction of about 76:24, followed by stirring at about 70° C. for about 4 hours to prepare a cleaning solution.

### Cleaning Process

The cleaning solution was sprayed on a bare-Si substrate, a silicon substrate with an amorphous silicon (a-Si) layer, a silicon substrate with a Cu layer, a silicon substrate with a Co layer, a silicon substrate with a SiCOH layer, a silicon substrate with a SiN layer, and a silicon substrate with a poly-Si layer, each of which include SiO₂ and SiN contaminant particles. Here, the spraying of the cleaning solution was performed for about 60 seconds by a spin coating process. After thin films were formed, ultrapure distilled water (DIW) was sprayed for about 40 seconds, and then acetone was sprayed for about 40 seconds.

### Analysis and Results

### 1-1. Peeling Analysis of Thin Film

To confirm that the thin films were peeled by DIW, atomic force microscopy (AFM) images and scanning electron microscope (SEM) images of a bare-Si substrate and a bare-Si substrate after performing the cleaning process (Comparative Example 1) were measured.

### 1-2. Peeling Analysis Result of Thin Film

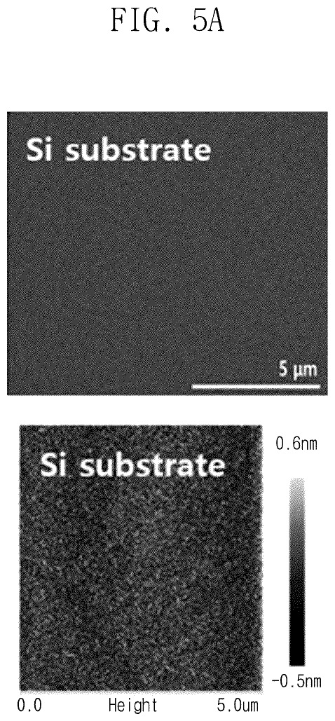

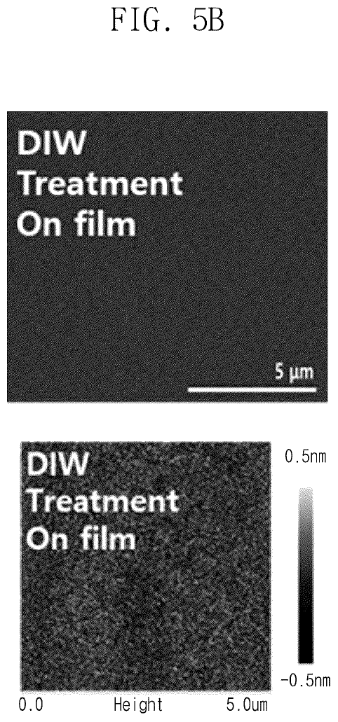

FIG. 5A show an AFM image and an SEM image of a bare-Si substrate. FIG. 5B shows an AFM image and an SEM image of a bare-Si substrate after performing a cleaning process.

Referring to FIGS. 5A and 5B, it may be confirmed that the thin film is completely peeled off by DIW.

### 2-1. Surface Energy and Contact Angle Analysis of Thin Film

Contact angles of DIW and diiodomethane (DIM) were measured on thin films, and surface energy was analyzed using the same. The surface energy was analyzed using Equation 1 below.

$$1 + cos θ = \frac{2 {( {γ}_{s}^{d} )}^{0.5} {( {γ}_{lv}^{d} )}^{0.5}}{{γ}_{lv}} + \frac{2 {( {γ}_{s}^{p} )}^{0.5} {( {γ}_{lv}^{p} )}^{0.5}}{{γ}_{lv}} \qquad [ Equation 1 ]$$

$${γ}_{s} = {γ}_{s}^{d} + {γ}_{s}^{p}$$

In Equation 1, θ: contact angle, γₗᵥ^{d}: dispersive component of liquid (mN/m), γₗᵥ^{p}: polar component of liquid (mN/m), γₛ^{d}: dispersive component of solid (mN/m), γₛ^{p}: polar component of solid (mN/m), γₛ: surface energy of solid (mN/m).

### 2-2. Surface Energy and Contact Angle Analysis Results of Thin Film

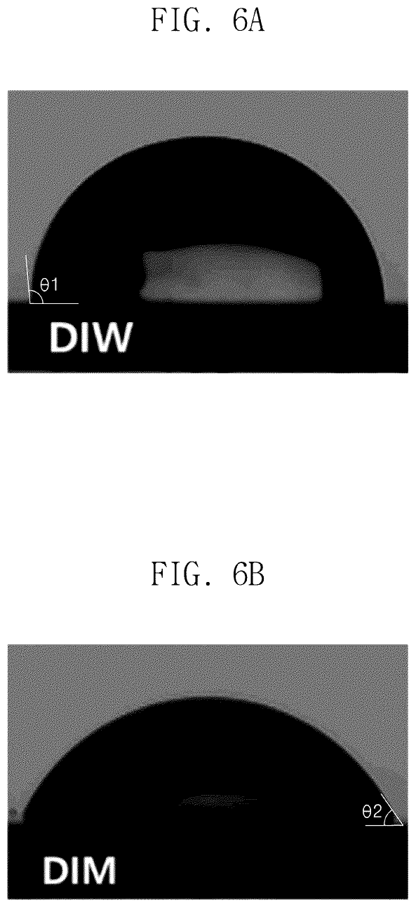

FIG. 6A is an image obtained by measuring a contact angle of DIW on a thin film. FIG. 6B is an image obtained by measuring a contact angle of DIM on a thin film.

Referring to FIGS. 6A and 6B, a contact angle θ1 of the DIW is about 93.15° and a contact angle θ2 of the DIM is about 47.40°. Table 3 below shows surface energy factor values of DIW and DIM. Here, the surface energy of the thin film may be calculated as shown in Table 4 below.

TABLE 3

| Liquid | γₗᵥ^{d}(mN/m) | γₗᵥ^{P}(mN/m) | γₗᵥ(mN/m) |
|---|---|---|---|
| DIW | 21.8 | 51 | 72.8 |
| DIM | 50.8 | 10 | 50.8 |

TABLE 4

| θ1(°) | θ2(°) | γₛ^{d}(mN/m) | γₛ^{p}(mN/m) | γₛ(mN/m) |
|---|---|---|---|---|
| 93.15 | 47.40 | 35.7113 | 0.8279 | 36.54 |

Accordingly, it may be seen that the thin film including PVDF is hydrophobic because the contact angle θ1 of DIW is greater than 90, and the surface energy with respect to water is formed as low as about 36 mN/m. In general, in the case of a hydrophilic SiO₂ substrate, the surface energy is about 50 mN/m or more.

### 3-1. Analysis of Cleaning Efficiency on Hydrophobic Substrate

After measuring the SEM images of the hydrophobic substrates (e.g., silicon substrates formed with a-Si layer, Cu layer, Co layer, and SiCOH layer, respectively) and the bare-Si substrate before and after performing the cleaning process, the number of contaminating particles was analyzed using the ImageJ program. Before the cleaning process, an average of about 500 contaminant particles were distributed per about 100 um2 area, cleaning efficiency was calculated using Equation 2 below. Then, an effective surface area of the remaining particles was calculated through AFM measurement.

$$Partical removal efficiency = \frac{\begin{matrix}number of particles before cleaning - \\ number of particles after cleaning\end{matrix}}{number of particles before cleaning} \qquad [ Equation 2 ]$$

An effective surface area simulation value means a value of a critical effective surface area. This is the minimum value of an energy gain at which particles are capable of being removed, and means a point at which the energy gain is equal to an interfacial energy between the substrate and the particles.

### 3-2. Analysis Result of Cleaning Efficiency on Hydrophobic Substrate

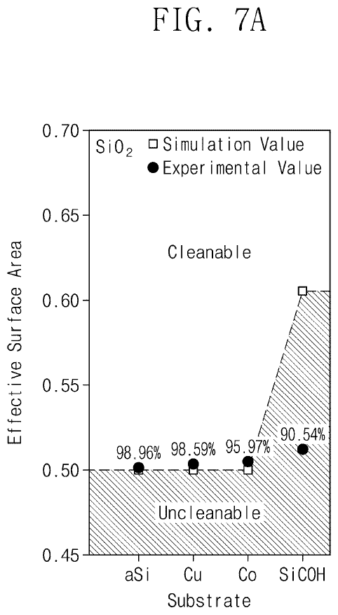

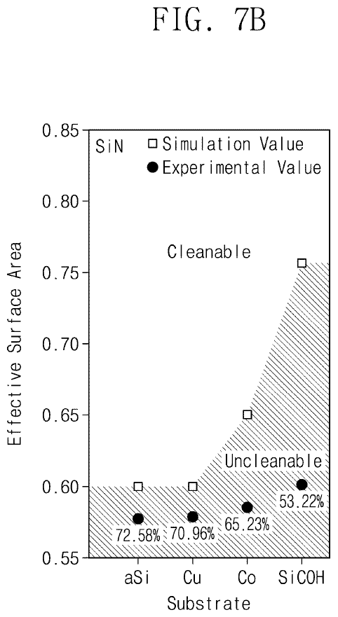

FIG. 7A is a graph showing cleaning efficiency of SiO₂ contaminant particles on a hydrophobic substrate. It shows the cleaning efficiency and effective surface area (experiment and simulation) depending on a type of substrate. FIG. 7B is a graph showing cleaning efficiency of SiN contaminant particles on a hydrophobic substrate. It shows the cleaning efficiency and effective surface area (experiment and simulation) depending on the type of substrate. Table 5 below shows the cleaning efficiency and effective surface area (experiment and simulation) of SiO₂ contaminant particles depending on the type of substrate. Table 6 below shows the cleaning efficiency and effective surface area (experiment and simulation) of SiN contaminant particles depending on the type of substrate.

TABLE 5

| | Cleaning | Effective | Simulation |
|---|---|---|---|
| Substrate | efficiency (%) | surface area | value |
| SiCOH | 90.54 | 0.515 | 0.605 |
| a-Si | 93.96 | 0.502 | 10.5 |
| Cu | 98.59 | 0.504 | 0.5 |
| Co | 95.97 | 0.506 | 0.5 |
| Bare-Si | 98.57 | 0.502 | 0.5 |

TABLE 6

| | Cleaning | Effective | Simulation |
|---|---|---|---|
| Substrate | efficiency (%) | surface area | value |
| SiCOH | 53.22 | 0.601 | 0.756 |
| a-Si | 72.58 | 0.577 | 0.60 |
| Cu | 70.96 | 0.577 | 0.60 |
| Co | 65.23 | 0.585 | 0.65 |
| Bare-Si | 76.56 | — | 0.55 |

In the case of SiO₂ contaminant particles, a high cleaning efficiency of about 90% or more may be observed, and it is effective even for particles with severe physical deformation. In the case of SiN contaminant particles, a high cleaning efficiency of about 50% or more may be observed, and it is effective even for contaminant particles having an effective surface area of about 0.55 or more. For example, it may be confirmed that the cleaning efficiency is relatively high on the hydrophobic substrate.

### 4-1. Analysis of Cleaning Efficiency on Hydrophilic Substrate

After measuring the SEM images of the hydrophilic substrates (e.g., silicon substrates formed with SiN layer, TiN layer, and poly-Si layer, respectively, and silicon substrate) before and after performing the cleaning process, the number of contaminating particles was analyzed using the ImageJ program. Before the cleaning process, an average of about 500 contaminant particles were distributed per about 100 um2 area, cleaning efficiency was calculated using Equation 2 above. Then, an effective surface area of the remaining particles was calculated through AFM measurement.

### 4-2. Analysis Result of Cleaning Efficiency on Hydrophilic Substrate

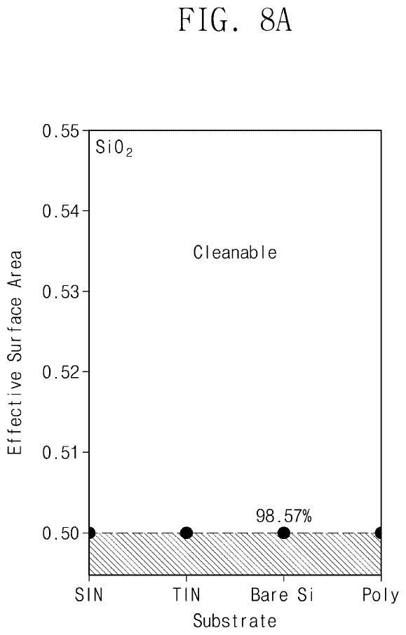

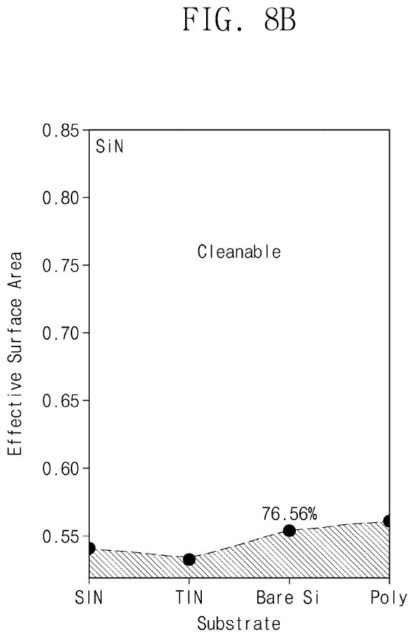

FIG. 8A is a graph showing cleaning efficiency of SiO₂ contaminant particles on a hydrophilic substrate. It shows the cleaning efficiency and effective surface area depending on a type of substrate. FIG. 8B is a graph showing cleaning efficiency of SiN contaminant particles on a hydrophilic substrate. It shows the cleaning efficiency and effective surface area depending on the type of substrate.

In the case of SiO₂ contaminant particles, a high cleaning efficiency of about 90% or more may be observed, and it is effective even for particles with severe physical deformation. In the case of SiN contaminant particles, a high cleaning efficiency of about 70% or more may be observed, and it is effective even for contaminant particles having an effective surface area of about 0.55 or more. For example, it may be confirmed that the cleaning efficiency is high on the hydrophilic substrate.

According to the present inventive concept, the semiconductor cleaning including the hydrophobic polymer has a relatively high cleaning efficiency for both hydrophobic and hydrophilic substrates. Accordingly, it has cleaning power for a plurality of layer materials used in the pre-processing process (FEOL) and post-processing process (BEOL) of the semiconductor manufacturing process. Therefore, it is possible to provide the method of manufacturing a semiconductor with increased efficiency.

In addition, the hydrophobic polymer of the semiconductor cleaning composition according to some embodiments of the present inventive concept may include the polar allotrope, and thus, the thin film may be easily peeled by using water, the damage to the substrate may be reduced, and a stable method of manufacturing the semiconductor may be provided.

While the present inventive concept has been particularly shown and described with reference to example embodiments thereof, it will be apparent to those of ordinary skill in the art that various changes in form and detail may be made thereto without departing from the spirit and scope of the present inventive concept.

What is claimed is:

1. A semiconductor cleaning composition comprising:
a hydrophobic polymer;
an organic acid; and
a solvent,
wherein the hydrophobic polymer includes a first allotrope and a second allotrope,
wherein the first allotrope is nonpolar,
wherein the second allotrope is polar, and
wherein the second allotrope is about 5% to about 20% of the hydrophobic polymer.

2. The semiconductor cleaning composition of claim 1, wherein the hydrophobic polymer includes poly(vinylidene fluoride) (PVDF) or PVDF copolymer.

3. The semiconductor cleaning composition of claim 2, wherein the second allotrope is about 6% to about 10% of the hydrophobic polymer.

4. The semiconductor cleaning composition of claim 1, wherein a concentration of the hydrophobic polymer is about 5 to about 7 wt %, and
wherein a concentration of the organic acid is about 1 to about 1.5 wt %.

5. The semiconductor cleaning composition of claim 1, wherein the organic acid includes at least one of oxalic acid or malic acid.

6. The semiconductor cleaning composition of claim 1, wherein the solvent includes at least one of dimethylformamide (DMF), dimethylacetamide (DMA), or dimethyl sulfoxide (DMSO).

7. The semiconductor cleaning composition of claim 1, wherein an average molecular weight of the hydrophobic polymer is about 180 to about 700 kg/mol.

8. The semiconductor cleaning composition of claim 1, wherein the hydrophobic polymer includes poly(vinylidene fluoride)-co-hexafluoropropylene (PVDF-HFP) copolymer.

9. A method of manufacturing a semiconductor, the method comprising:
providing a cleaning solution;
spraying the cleaning solution on a substrate;
forming a thin film on the substrate by using the cleaning solution; and
spraying distilled water on the thin film,
wherein the cleaning solution includes a hydrophobic polymer and an organic acid, and
wherein the thin film is separated from the substrate by the spraying of the distilled water.

10. The method of claim 9, wherein the hydrophobic polymer includes a first allotrope and a second allotrope,
wherein the first allotrope is nonpolar,
wherein the second allotrope is polar, and
wherein the second allotrope is about 5% to about 20% of the hydrophobic polymer.

11. The method of claim 10, wherein the second allotrope is about 6% to about 10% of the hydrophobic polymer.

12. The method of claim 9, wherein a concentration of the hydrophobic polymer is about 5 to about 7 wt %, and
wherein a concentration of the organic acid is about 1 to about 1.5 wt %.

13. The method of claim 9, wherein the hydrophobic polymer includes poly(vinylidene fluoride) (PVDF) or a PVDF copolymer.

14. The method of claim 9, wherein the organic acid includes at least one of oxalic acid or malic acid.

15. The method of claim 9, further comprising spraying acetone on the substrate after the spraying of the distilled water on the thin film.

16. The method of claim 9, wherein contaminant particles are provided on the substrate, and the thin film is formed on the contaminant particles, wherein the contaminant particles include SiO₂ or SiN.

17. The method of claim 9, wherein the substrate is a hydrophilic substrate or a hydrophobic substrate.

18. A method of manufacturing a semiconductor, the method comprising:
providing a cleaning solution including a semiconductor cleaning composition;
spraying the cleaning solution on a substrate;
forming a thin film on the substrate by using the cleaning solution;
spraying distilled water on the thin film; and
spraying acetone on the substrate,
wherein the thin film is separated from the substrate by the spraying of the distilled water,
wherein the semiconductor cleaning composition includes:
a hydrophobic polymer;
an organic acids; and
a solvent,
wherein the hydrophobic polymer includes a first allotrope and a second allotrope,
wherein the first allotrope is nonpolar,
wherein the second allotrope is polar,
wherein the second allotrope is about 6% to about 10% of the hydrophobic polymer,
wherein a concentration of the hydrophobic polymer is about 5 to about 7 wt %, and
wherein a concentration of the organic acid is about 1 to about 1.5 wt %.

19. The method of claim 18, wherein the hydrophobic polymer includes poly(vinylidene fluoride) (PVDF).

20. The method of claim 18, wherein the hydrophobic polymer includes poly(vinylidene fluoride)-co-hexafluoropropylene (PVDF-HFP) copolymer.
